(19) United States
(12) Patent Application Publication
(10) Pub. No.: US 2003/0099779 A1
(43) Pub. Date: May 29, 2003

(54) Method and device for thermal spraying for the coating of surfaces

(75) Inventor: Dieter Kley, Castrop-Rauxel (DE)

Correspondence Address: JACOBSON HOLMAN PLLC, 400 SEVENTH STREET N.W., SUITE 600, WASHINGTON, DC, 20004, US

(73) Assignee: Grillo-Werke AG,, Duisburg (DE)

(21) Appl. No.: 10/338,734

(22) Filed: Jan. 9, 2003

Related U.S. Application Data
(63) Continuation of application No. 09/807,979, filed on Apr. 30, 2001.
Application No. 09/807,979 is a 371 of international application No. PCT/EP99/08247, filed on Oct. 29, 1999.

(30) Foreign Application Priority Data
Oct. 31, 1998 (DE) 298 19 453.8

(51) Int. Cl. B05D 1/08; C23C 16/00

(52) U.S. Cl. 427/455; 118/723 DC

(57) ABSTRACT

The method for thermal spraying, especially of metals, for the coating of surfaces, wherein the material employed for coating is supplied in the form of a wire, molten and sprayed, uses a plasma arc.

### METHOD AND DEVICE OF THERMAL SPRAYING FOR THE COATING OF SURFACES

The present invention is related to a method and a device for thermal spraying, especially of metals, for the coating of surfaces, wherein the material employed for coating is supplied in the form of a wire, molten and sprayed.

Devices of this kind are known in different designs. Thus, for example, manually operated spray guns are known in which two wires are mutually approached at an angle by feeding means in front of an atomizing gas nozzle, wherein an arc melting the wire material is produced between the wire ends.

It is also known to produce a melting flame within the spraying head by means of which the material to be sprayed is molten, wherein the molten particles are then transported by compressed air or the like onto the surface to be coated. Merely in an illustrative manner for arc technology, EP-0 239 585 B with further references may be mentioned.

The object of the invention has been to provide a method and a device for the spraying of metallic wire wherein at least one of the electrodes is not destroyed. A high efficiency, a low noise level and easy handling are to be ensured.

According to the invention, with the method and the device of the kind mentioned above, this object is achieved by producing the melting energy by a plasma arc, wherein the arc is formed between a non-melting stationary electrode and a melting electrode in the form of the wire, and the molten material is sprayed in the direction of wire feeding.

Torch heads with a plasma arc are as such known as cutting heads to be employed for the cutting of metal sheets and operated with compressed air. In this arc plasma cutting, the heat energy and the kinetic energy of an ionized gas column (plasma) are utilized to melt the metal and displace it from the cutting gap. This property is utilized by the invention in that the plasma arc is a compressed-air plasma arc, and a wire for atomizing is fed to such a plasma cutting head. Preferably, the arc is formed between a non-melting stationary electrode and a melting wire. The molten material is sprayed in the direction of wire feeding. The plasma arc is first ignited between the two electrodes. An electrically conductive wire takes the function of an electrode. After ignition, the wire, which is consuming away, is advanced accordingly.

Further embodiments of the invention can be seen from the dependent claims; in particular, as mentioned above, the torch head may be designed as a compressed-air plasma arc torch. Conveniently, the feeding nozzle for the wire with the atomizing gas is arranged at an angle with the center line of the plasma torch; for example, in a further embodiment, this angle between the wire feed and the plasma torch center line is about 75°.

Conveniently, the centric wire feed is surrounded by the atomizing gas nozzle in an annular arrangement.

It may be advantageous when an inert gas plasma torch is associated with the atomizing gas nozzle, and/or that a non-metallic wire can be associated with the atomizing gas nozzle for melting and spraying.

A particular advantage of the invention resides in the fact, inter alia, that a higher melting rate can be accomplished; the application efficiency can be increased by at least 10%, dust formation and evaporation of material being reduced.

In a further embodiment, depending on the application of the device according to the invention, at least two torch heads with associated wire feeding and atomizing gas nozzles may be provided. In this case, it is possible to supply different materials to the different torch heads and then to apply the mixture of materials to the surface to be coated.

Further details, advantages and features of the invention are seen from the following description and drawing.

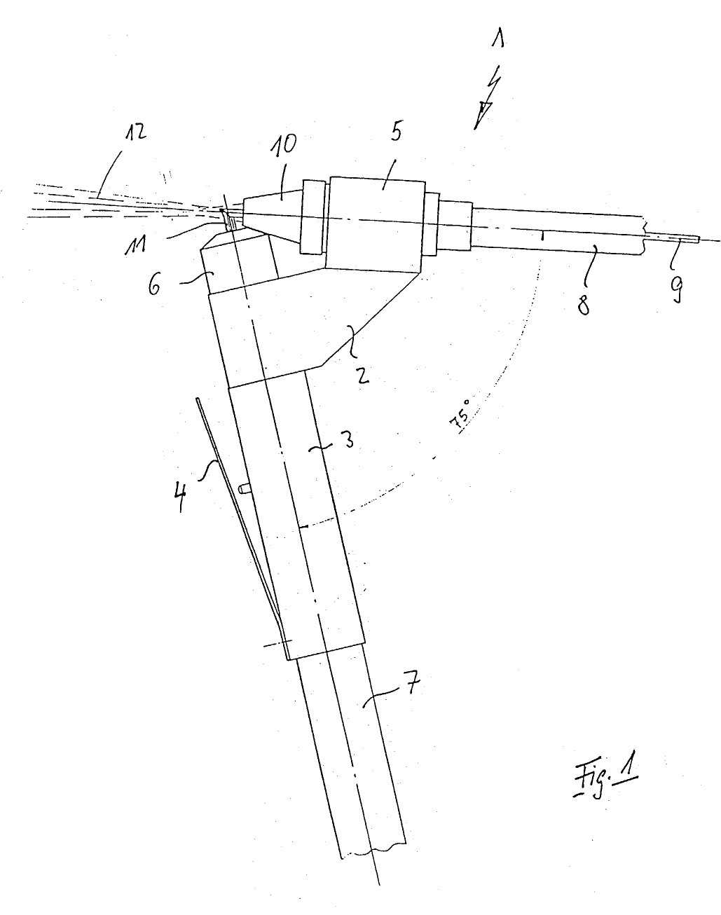

FIG. 1 shows a simplified reproduction of a device according to the invention; and

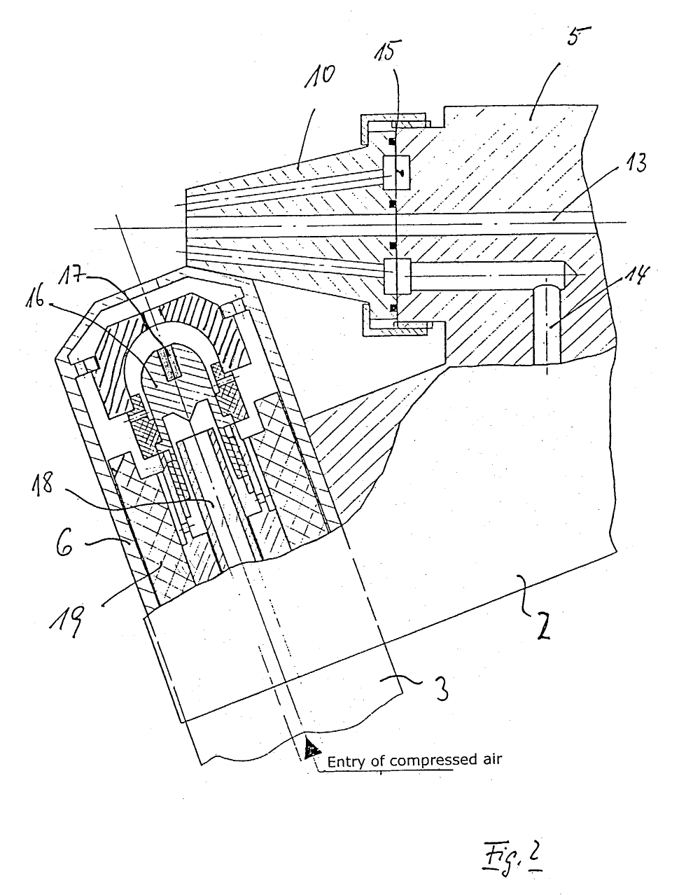

FIG. 2 shows an enlarged sectional representation of the head design of the device according to the invention.

The device, generally indicated by 1, consists of a spray gun housing 2 with a handle 3 designed as an actuating switch 4, wherein a spray wire supply head 5 and a compressed-air plasma torch head 6 whose center lines form an angle of 75° in the example represented here are associated with the housing 2. A merely outlined bundle of flexible tubes 7 with electric power supply and compressed air supply is associated with the plasma torch head 6, while a flexible supply tube 8 for the wire 9 is associated with the wire supply head. The compressed air is supplied via the housing 2, as can be seen, in particular, from FIG. 2.

The wire 9 exits from the front of the atomizing gas nozzle 10 and is molten in a plasma arc 11 and projected as, a spray jet 12 onto a non-represented surface by means of the atomizing gas.

In FIG. 2, the wire to be molten is not itself represented, but only a wire duct 13 is shown which is centrically passing through the atomizing gas nozzle 10. The atomizing gas is supplied through the housing 2 via corresponding ducts 14 to a ring chamber 15, which in turn surrounds the duct 13 for the wire in an essentially centric arrangement. Inside the plasma torch head 6, an electrode 16 with a Zr/Hf insert 17 is provided, and in this case too, a centric compressed air supply 18 is provided which is surrounded by insulating members 19.

Not represented in detail are controlling means which provide for that, for example, the compressed air supply rate for the plasma torch 6 and the compressed air supply rate for the formation of the atomizing gas jet can be set differently.

Of course, the described example of the invention can be modified in various ways without deviating from the basic idea. Thus, the arc can be produced not only between the torch as a cathode and, for example, the spray wire as an anode, as represented in the Figure, but it can also be produced within the torch between a cathode and an anode, so that electrically non-conducting wires, for example, plastic-sheathed oxide powder fill wires, can also be processed. This embodiment renders the device more flexible in the processing of various materials.

1. A method for thermal spraying, especially of metals, for the coating of surfaces, wherein the material employed for coating is supplied in the form of a wire, molten and sprayed, characterized in that the melting energy is produced by a plasma arc, wherein the arc is formed between a non-melting stationary electrode and a melting electrode in the form of the wire, and the molten material is sprayed in the direction of wire feeding.

2. The method according to claim 1, characterized in that said wire is surrounded by the atomizing gas in an annular arrangement.

3. The method according to claim 1 or 2, characterized in that said plasma arc is a compressed-air plasma arc.

4. The method according to any of the preceding claims, characterized in that said atomizing gas is an inert gas or compressed air.

5. The method according to any of the preceding claims, characterized in that said wire is advanced at a settable angle with the center line of the plasma arc.

6. The method according to any of the preceding claims, characterized in that the angle between the wire and plasma arc is about 75°.

7. A device for thermal spraying, especially of metals, for the coating of surfaces, wherein the material employed for coating is supplied in the form of a wire, molten and sprayed, characterized in that a torch head (6) producing a plasma arc (11) is provided for producing the melting energy.

8. The device according to claim 7, characterized in that said torch head (6) is designed as a compressed-air plasma arc torch.

9. The device according to claim 7 or 8, characterized in that the supply nozzle (5) for the wire with the atomizing gas nozzle (10) is arranged at a settable angle with the medium line of the plasma torch (6).

10. The device according to any of the preceding claims, characterized in that the angle between the wire supply (8) and the plasma torch (6) is about 75°.

11. The device according to any of the preceding claims, characterized in that said atomizing gas nozzle (10) surrounds the centric wire supply (13) in an annular arrangement.

12. The device according to any of the preceding claims, characterized in that an inert gas plasma torch is associated with the atomizing gas nozzle.

13. The device according to any of the preceding claims, characterized in that a non-metallic wire is associated with the atomizing gas nozzle for melting and spraying.

14. The device according to any of the preceding claims, characterized in that at least two torch heads with related wire supply and atomizing gas nozzles are provided.
